(19) United States
(12) Patent Application Publication
(10) Pub. No.: US 2002/0140496 A1
(43) Pub. Date: Oct. 3, 2002

(54) Forward body biased transistors with reduced temperature

(76) Inventors: Ali Keshavarzi, Portland, OR (US); Vivek K. De, Beaverton, OR (US); Shekhar Y. Borkar, Beaverton, OR (US)

Correspondence Address: BLAKELY,SOKOLOFF,TAYLOR & ZAFMAN LLP, 12400 Wilshire Boulevard, Seventh Floor, Los Angeles, CA, 90025, US

(21) Appl. No.: 09/505,212

(22) Filed: Feb. 16, 2000

(51) Int. Cl. H03K 3/01

(52) U.S. Cl. 327/534

(57) ABSTRACT

In some embodiments, the invention involves an electrical system including a die having field effect transistors (FETs), the die having a target acceptable leakage level. A body bias voltage source to apply a voltage Vbb1 to bodies of the FETs to forward body bias the FETs. A temperature reduction system to provide a temperature reduction to the die such that the die is in a temperature range, and wherein when the temperature of the die is in the temperature range and the voltage Vbb1 is applied to the bodies, a leakage of the die is not more than the target acceptable leakage level, but if the temperature reduction system were not operated and the voltage Vbb1 is applied to the bodies, then the leakage would be above the target acceptable leakage level. Other embodiments are described and claimed.

### BACKGROUND OF THE INVENTION

1. Technical Field of the Invention

The present invention relates to circuits and semiconductor dice and, more particularly, to forward body biased transistors in a die with reduced temperature.

2. Background Art

Low temperature complementary metal oxide semiconductor (CMOS) operation has been used to improve performance of an integrated circuit by increasing the transistor drive current through improving carrier mobility. Other advantages include improved subthreshold slope and swing. This allows for lowering the threshold voltage (Vt) for a given current I_{OFF} constraint and hence resulting in a better gate overdrive for a given supply voltage and hence higher drive current. Forward body bias (FBB) circuit techniques also improve the performance of CMOS circuits and may be used indirectly to lower power by allowing voltage scaling to smaller supply voltages. An advantage of forward body bias is improved Short Channel Effects (SCE). A drawback of forward body bias is degradation in subthreshold slope or swing and an increase in junction leakage.

Body bias refers to the relationship between voltage of the source (Vsource) of a field effect transistor (FET) and voltage of the body (Vbody or Vbb) of the FET. N-channel FETs (NFETs) have sources, drains, and bodies with voltages Vsource, Vdrain, and Vbody. N-channel metal oxide semiconductor field effect transistors (NMOSFETs) are examples of NFETs. NFETs are zero body biased when Vbody=Vsource, reverse body biased when Vbody<Vsource, and forward body biased when Vbody>Vsource. The amount of FBB for NFETs is measured by Vbody−Vsource, which equals Vbody when Vsource is at ground (sometimes referred to as Vss). P-channel FETs (PFETs) have sources, drains, and bodies with voltages Vsource, Vdrain, and Vbody. P-channel metal oxide semiconductor field effect transistors (PMOSFETs) are examples of PFETs. PFETs are zero body biased when Vbody=Vsource, reverse body biased when Vbody>Vsource, and forward body biased when Vbody<Vsource. The amount of FBB for PFETs is measured by Vsource−Vbody, which equals Vcc−Vbody in cases where Vsource is at the voltage of the power supply signal Vcc (sometimes referred to as Vdd).

The threshold voltage (Vt) of a FET decreases as the FET becomes more forward biased and increases as the FET becomes less forward biased or more reverse biased. The leakage of a FET increases as the FET becomes more forward biased and decreases as the FET becomes less forward biased or more reverse biased.

### BRIEF DESCRIPTION OF THE DRAWINGS

The invention will be understood more fully from the detailed description given below and from the accompanying drawings of embodiments of the invention which, however, should not be taken to limit the invention to the specific embodiments described, but are for explanation and understanding only.

FIG. 1 is a block diagram representation of an electrical system according to some embodiments of the invention.

FIG. 2 is a schematic side view of the package of FIG. 1 in a temperature reduction system.

FIG. 3 is a graphical representation of drain current as a function of gate voltage.

FIG. 4 is a graphical representation of drain current as a function of gate voltage at different bias values and temperatures.

FIG. 5 illustrates forward body biased circuitry and body bias voltage sources according to some embodiments of the invention.

FIG. 6 is a schematic representation of an inverter circuit according to some embodiments of the invention.

### DETAILED DESCRIPTION

The invention involves an electrical system having a die with a target acceptable leakage level. The target acceptable leakage level may be expressed as a maximum/worst case level. It may be the worst case in a range. In some embodiments of the invention, FETs are body biased to a level considering a temperature reduction and kept within the leakage level.

System Overview

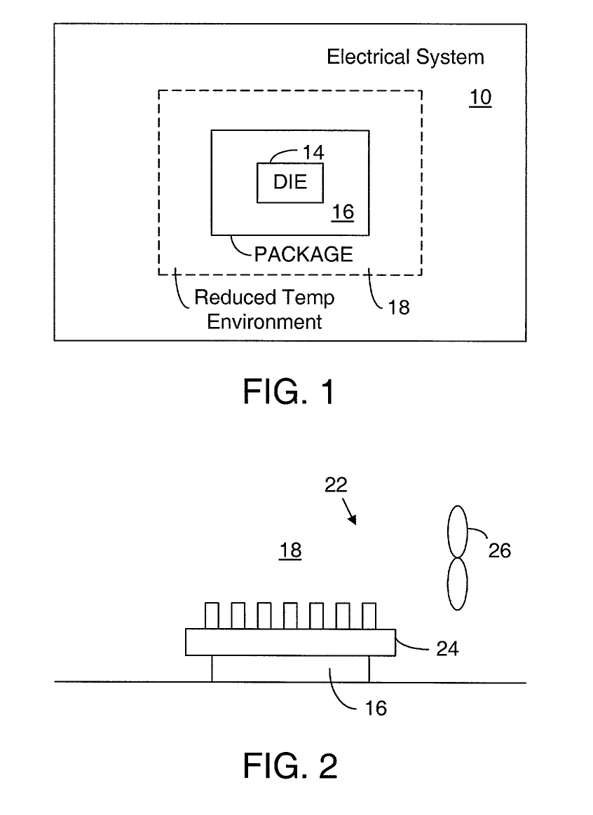

Referring to FIG. 1, an electrical system 10 includes a die 14 includes transistors that are forward body biased. The forward body bias may be constant or selective. For example, the body bias may be forward during a high performance mode and zero or reverse during a standby or low power mode. Electrical system 10 may be included in any of a variety of electrical systems. For example, electrical system 10 may be included in a computer system, such as a laptop computer, hand held computer, desktop computer, server, etc. Die 14 may be packaged in package 16, although that is not required.

Die 14 is in a reduced temperature environment 18. A temperature reduction system is used to create the reduced temperature of reduced temperature environment 18. For example, referring to FIG. 2, a temperature reduction system 22 includes a heat sink 24 connected to package 16 (which includes die 14) and a fan 26. (Temperature reduction system 22 may include additional components not illustrated.) The temperature of die 14 is reduced through a temperature gradient created between the higher temperature die and the lower temperature reduced temperature environment. In the particular example of FIG. 2, fan 26 blows air through the reduce temperature environment 18 to replace higher temperature air with lower temperature air. Note that although reduced temperature environment 18 is illustrated as being bounded by a dashed-lined rectangle, the actual boundaries of reduced temperature environment 18 are not important as long as the temperature of die 14 is reduced over what it would be with no temperature reduction system.

A temperature reduction system may include a variety of other components in addition to or in place of those illustrated in FIG. 2. Temperature reduction systems are well known in the prior art. For example, the temperature reduction system may include liquid filled heat pipes wherein the liquid therein experiences a phase change to remove heat. These heat pipes may be passive. Active temperature reduction may be used. Other possible components for the temperature reduction system include Peltier temperature reduction techniques and vapor phase refrigeration. The invention is not limited to any particular type of temperature reduction system.

The amount of temperature reduction is somewhat controllable. For example, a bigger or higher frequency fan can provide a greater temperature reduction.

Curves Illustrating Effect of Forward Body Bias and Temperature

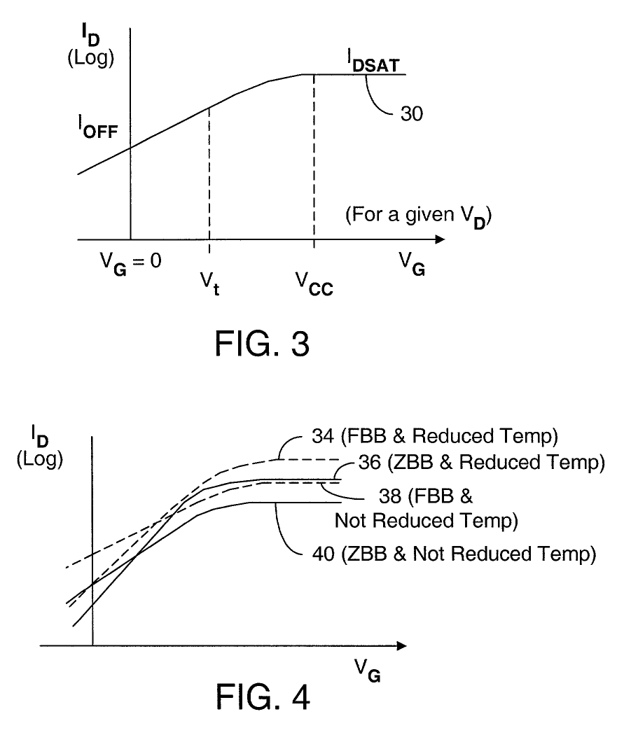

FIG. 3 illustrates a curve 30 showing FET drain current I_{D} as a function of gate voltage V_{G} (with respect to source voltage) for a given drain bias voltage V_{D} (with respect to the source) e.g., V_{D}=V_{CC}. The drain current is sometimes called drive current. The curve of FIG. 3 is intended only to show general relationships, not to give an exact representation. As shown in FIG. 3, at the gate voltage V_{G}=0, the drain current I_{D} is referred to as I_{OFF}. As V_{G} increases past the threshold voltage V_{T} to FET power supply voltage V_{CC} (sometimes called V_{DD}), the drain current I_{D} increases from I_{OFF} to a drain saturation current I_{DSAT}.

FIG. 4 illustrates curves 34, 36, 38, and 40, which show general relationships of the effect of forward body bias (FBB) and temperature on FET drain current as a function of gate voltage. The curves of FIG. 4 are not intended to be precise, but rather to merely illustrate general principles. For example, curves 34 and 40 do not have to have identical I_{OFF} values. Either of 34 or 40 could have the higher I_{OFF} values. Likewise, either of curves 36 or 38 could have a higher I_{OFF} value. Also, the point at which the curves cross each other could be somewhat different. (Note that curves 34, 36, 38, and 40 of FIG. 4 are not intended to line up exactly with curve 30 of FIG. 3.)

Generally, reducing the temperature of a die has the effect of reducing leakage current (which decreases I_{OFF}), increasing the slope of the I_{D} current curve between V_{G}=0 and V_{G}=V_{CC} (i.e., making the slope of the curve steeper), and increasing the value of saturation current I_{DSAT}. Generally, increasing the amount of forward body bias has the effect of increasing leakage (which increases I_{OFF}), decreasing the slope of the I_{D} current curve between V_{G}=0 and V_{G}=V_{CC} (i.e., making the slope of the curve less steep), and increasing the amount of forward body bias may also increase the value of saturation current I_{DSAT}.

The following table summarizes which curve has which feature.

| Body Bias | Temperature | Curve |
|---|---|---|
| Forward (FBB) | Reduced | 34 |
| Zero (ZBB) | Reduced | 36 |
| Forward (FBB) | Not Reduced | 38 |
| Zero (ZBB) | Not Reduced | 40 |

It is noted that while a zero body biased FET is used in the comparison, a reverse body biased FET or less forward body biased FET could be used. Further, the comparison is made with reduced and not reduced temperature. It could rather be made with reduced or more reduced temperatures.

As can be seen, a FET that is both forward body biased and that has a reduced temperature has the highest I_{DSAT} (for a given target I_{OFF} leakage). However, a FET with a zero body bias and reduced temperature has the lowest drain current I_{D}. Accordingly, the forward body bias that contributes to the highest I_{DSAT} also contributes to a higher I_{OFF}. Accordingly, in some respects, temperature reduction and application of forward body bias are complementary for having high drive current at a reasonably low leakage constraint. The designer of the die can consider the amount of temperature reduction in choosing the amount of forward body bias. Or, the system designer can consider the amount of forward body bias in choosing the amount of temperature reduction.

For example, consider an electrical system having a die having a target acceptable leakage level. At least some of the FETs are forward body biased. The body biased FETs can include PFETs and NFETs or only PFETs or only NFETs. A voltage Vbb1 may be used to create the forward body bias. (There may be additional FETs body biased at other values.) The temperature reduction system provides a temperature reduction to the die such that the die is in a temperature range. When the temperature of the die is in the temperature range and the voltage Vbb1 is applied to the bodies, a leakage of the die is not more than the target acceptable leakage level. However, if the temperature reduction system were not operated and the voltage Vbb1 is applied to the bodies, then the leakage would be above the target acceptable leakage level.

Merely as example, if the temperature reduction system were not operated, and a voltage Vbb2 were applied to the bodies, then the leakage would not be above the target acceptable leakage level, where Vbb1 is more than 15% greater than Vbb2. As another example, if the temperature reduction system were not operated, and a voltage Vbb2 were applied to the bodies, then the leakage would not be above the target acceptable leakage level, where Vbb1 is more than 25% greater than Vbb2. However, the invention is not restricted to these particular examples.

Consider another example. An electrical system includes a die has a target acceptable leakage level with the FETs each having an I_{OFF} level that is greater than would be acceptable to meet the target acceptable leakage level without temperature reduction. A body bias voltage source to apply a voltage Vbb1 to bodies of the FETs to forward body bias the FETs. A temperature reduction system provides temperature reduction to the die such that the die is in a temperature range. When the temperature of the die is in the temperature range and the voltage Vbb1 is applied to the bodies, a leakage of the die is not more than the target acceptable leakage level.

Examples of Circuit Arrangements

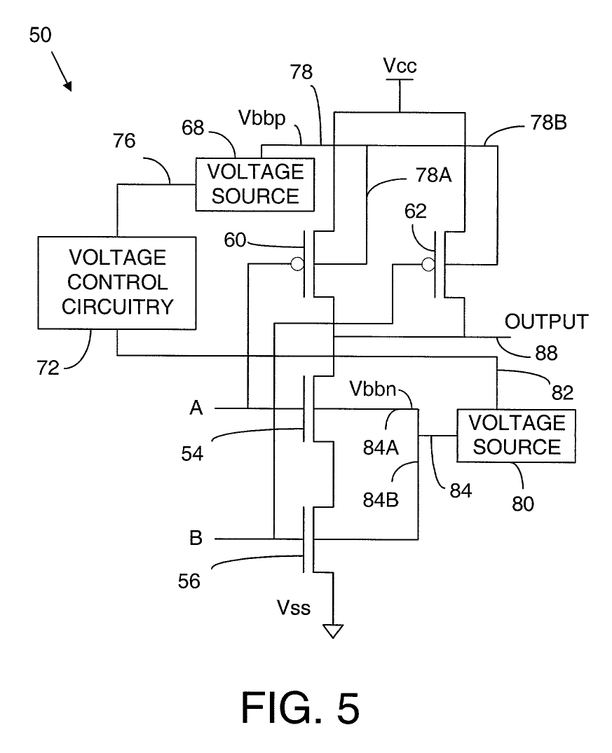

FETs according to the invention may be forward body biased through a variety of circuitry. For example, FIG. 5 illustrates a two-input NAND gate circuit 50 that may be included in die 14. Circuit 50 has inputs A and B at the gates of NFETs 54 and 56 and at the gates of PFETs 60 and 62. The drains of PFETs 60 and 62 are connected in parallel to the output of circuit 50 on conductor 88. The drain of NFET 54 is also connected to conductor output 88. As is well known, the voltage at conductor 88 is determined according to the logic of a NAND gate depending on the inputs A and B.

A voltage Vbbp is supplied to the bodies of FETs 60 and 62 on conductors 78 (including conductors 78A and 78B) from a body bias voltage source 68. In some embodiments, Vbbp can have different values depending on the mode. For example, in a high performance mode, Vbbp could forward body bias PFETs 60 and 62. In other embodiments, Vbbp could have a value to zero or reverse bias PFETs 60 and 62. In still other embodiments, voltage source 68 provides only one voltage for Vbbp. In some embodiments, the voltage provided by voltage source 68 is controlled by voltage control circuitry 72, which is optional.

Body bias voltage source 80 provides a voltage Vbbn to NFETs 54 and 56 through conductors 84, 84A, and 84B. Vbbn may have different values as described in connection with Vbbp or have a single value to forward body bias NFETs 54 and 56. In some respects, conductors 78 and 84 may be considered body bias voltage sources because the carry the body bias voltage. Voltages sources 68 and 80 and voltage control circuitry 72 (which interfaces with voltage sources 68 and 80 through conductors 78 and 82) may be on the same chip as the FETs to be body biased or on a different chip.

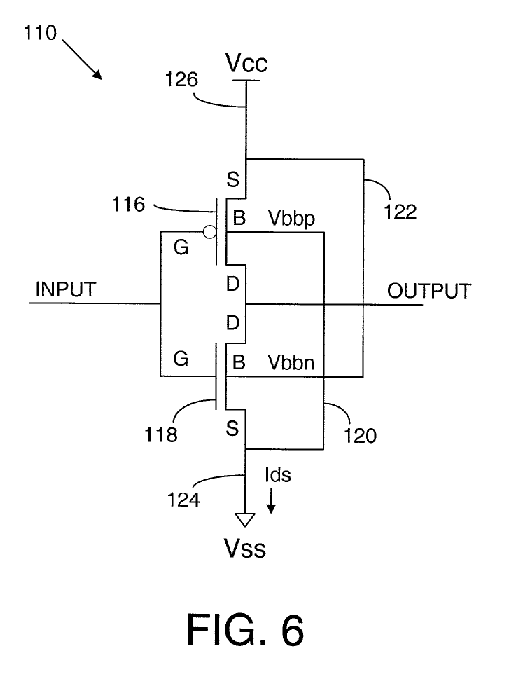

FIG. 6 illustrates another way in which FETs can be forward body biased. Referring to FIG. 6, a circuit 110 includes a PFET 116 and an NFET 118, each having a gate (G), drain (D), source (S), and body (B). Circuit 110 is an inverter circuit with an input at the gates and an output at the drains of transistors 116 and 118. Circuit 110 includes a supply voltage node 126 providing supply voltage (e.g., V_{CC} often called V_{DD}) and a ground voltage node 124 providing ground voltage (e.g., V_{SS}). The nodes are not necessarily connected to pads or other ports on the surface of the die. The supply and ground nodes and associated conductors to the bodies act as body bias voltage sources.

The supply and ground voltage nodes are not necessarily at the same voltages as supply and ground voltage pads or other ports, respectively, on the surface of the die. The supply and ground voltage nodes may also be the supply and ground voltage nodes, respectively, for various other circuits.

A voltage Vbbn is the voltage of the n-type body of PFET 116. The body of PFET 116 is forward biased by making Vbbn<Vcc. More specifically, the body of PFET 116 is coupled to ground voltage node 124 through conductor 120. The forward body bias applied to the body of PFET 116 is Vcc−Vbbp=Vcc−Vss=Vcc.

A voltage Vbbp is the voltage of the p-type body of NFET 118. The body of NFET 118 is forward biased by making Vbbn>Vss. More specifically, the body of NFET 118 is coupled to supply voltage node 126 through conductor 122. The forward body bias applied to the body of NFET 118 is Vbbn−Vss=Vcc−Vss=Vcc.

FETs 116 and 118 each have a threshold voltage Vt. The threshold voltages of transistors 116 and 118 are lowered because of the forward body bias. In an embodiment, Vcc is less than or equal to 700 millivolts, but may be higher. (If the forward body bias is greater than about 700 millivolts, there may be significant current between the source and body, which is generally undesirable.) For certain transistors and circuits, a Vcc of 450 to 500 millivolts may be optimal, but with cooling, a higher forward body bias may be desirable and hence a higher Vcc may be desirable in this combination. However, higher or lower Vcc levels may be optimal depending on the transistors or circuits involved. Depending on an intended Vcc, the transistors may be designed to provide the desired Vt when the forward body bias is applied.

The bias could be provided via the substrate, but this does not allow as many options. For example, in a p-substrate, all p-bodies for NFETs might have the same bias.

Other Information and Embodiments

In some embodiments, the insulating layer is positioned only under the source and drain, but not under the channel of at least some of the transistors. In some embodiments, insulating material can extend underneath the source, drain, and channel.

The body bias signals may be applied through various parts of the chip. For example, the Vbb signals (Vbbn and Vbbp) may be applied through two pins in a package for the chip. The bulk of the chip, where either p or n type transistors are fabricated, which may be exposed from the back side of the chip, to supply one of the two (Vbbn or Vbbp) bias signals. In a wire bond technology, the bulk of the chip (back-side) may rest on a conducting shelf, may be used to supply a body bias signal. In C4 technology, an additional conductor can be mounted on the back side of the die (typically a heat sink) which can be used to supply the bias. A body bias signal can be applied to the heat sink. The body bias signal(s) may be applied to the surface through taps into the bodies.

Isolating structures may be used between wells or transistors in wells and transistors not in wells. For example, a bias in a p-well may be isolated from an n-well and other p-wells that may have a different body bias.

In some embodiments, isolating dielectrics is positioned beneath the source and drain to reduced junction capacitance, but does not extend beneath the channel. In other embodiments, there is no isolation. In still other embodiments, the invention may be used in connection with SOI (silicon on insulator) configurations.

There may be intermediate structure (such as a buffer) or signals between two illustrated structures or within a structure (such as a conductor) that is illustrated as being continuous. The borders of the boxes in the figures are for illustrative purposes and not intended to be restrictive.

Also, as is well known, power supply and ground voltages are not necessarily constant, but rather have fluctuations because of noise, load, or other reasons.

FETs other than MOSFETs could be used. Although the illustrated embodiments include enhancement mode transistors, depletion mode transistors could be used with modifications to the circuit which would be apparent to those skilled in the art having the benefit of this disclosure.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the invention. The various appearances “an embodiment,” “one embodiment,” or “some embodiments” are not necessarily all referring to the same embodiments.

If the specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Those skilled in the art having the benefit of this disclosure will appreciate that many other variations from the foregoing description and drawings may be made within the scope of the present invention. Accordingly, it is the following claims including any amendments thereto that define the scope of the invention.

What is claimed is:

1. An electrical system, comprising:
a die including field effect transistors (FETs), the die having a target acceptable leakage level;
a body bias voltage source to apply a voltage Vbb1 to bodies of the FETs to forward body bias the FETs; and
a temperature reduction system to provide a temperature reduction to the die such that the die is in a temperature range, and wherein when the temperature of the die is in the temperature range and the voltage Vbb1 is applied to the bodies, a leakage of the die is not more than the target acceptable leakage level, but if the temperature reduction system were not operated and the voltage Vbb1 is applied to the bodies, then the leakage would be above the target acceptable leakage level.

2. The system of claim 1, wherein the die includes additional FETs, at least some of which are not forward body biased.

3. The system of claim 1, wherein if the temperature reduction system were not operated, and a voltage Vbb2 were applied to the bodies, then the leakage would not be above the target acceptable leakage level, where Vbb1 is more than 15% greater than Vbb2.

4. The system of claim 1, wherein if the temperature reduction system were not operated, and a voltage Vbb2 were applied to the bodies, then the leakage would not be above the target acceptable leakage level, where Vbb1 is more than 25% greater than Vbb2.

5. The system of claim 1, wherein the die is encased.

6. The system of claim 1, wherein the voltage source is a conductor.

7. The system of claim 6, wherein the conductor receives signals from a circuit on the die.

8. The system of claim 6, wherein the conductor receives signals from a circuit off the die.

9. The system of claim 1, wherein the electrical system is included in a portable computer.

10. The system of claim 1, wherein the body bias voltage source apply voltage Vbb1 to the bodies at only some times and applies another voltage for a low power mode at other times.

11. An electrical system, comprising:
a die including p-channel field effect transistors (PFETs) and n-channel field effect transistors (NFETs), the die having a target acceptable leakage level;
body bias voltage sources to apply a voltage Vbbp1 to bodies of the PFETs to forward body bias the PFETs and apply a voltage Vbbn1 to bodies of the NFETs to forward body bias the NFETs; and
a temperature reduction system to provide a temperature reduction to the die such that the die is in a temperature range, and wherein when the temperature of the die is in the temperature range and the voltages Vbbp1 and Vbbn1 are applied to the bodies, a leakage of the die is not more than the target acceptable leakage level, but if the temperature reduction system were not operated and the voltages Vbbp1 and Vbbn1 are applied to the bodies, then the leakage would be above the target acceptable leakage level.

12. The system of claim 11, wherein the die includes additional FETs, at least some of which are not forward body biased.

13. The system of claim 11, wherein if the temperature reduction system were not operated, and voltages Vbbp2 and Vbbn2 were applied to the bodies of the PFETs and NFETs, respectively, then the leakage would not be above the target acceptable leakage level, where Vbbp1 is more than 15% greater than Vbbn2 and Vbbn1 is more than 15% greater than Vbbp2.

14. The system of claim 11, wherein if the temperature reduction system were not operated, and voltages Vbbp2 and Vbbn2 were applied to the bodies of the PFETs and NFETs, respectively, then the leakage would not be above the target acceptable leakage level, where Vbbp1 is more than 25% greater than Vbbn2 and Vbbn1 is more than 15% greater than Vbbp2.

15. An electrical system, comprising:
a die including field effect transistors (FETs), the die having a target acceptable leakage level, the FETs each having an I_{OFF} level that is greater than would be acceptable to meet the target acceptable leakage level without temperature reduction;
a body bias voltage source to apply a voltage Vbb1 to bodies of the FETs to forward body bias the FETs; and
a temperature reduction system to provide a temperature reduction to the die such that the die is in a temperature range, and wherein when the temperature of the die is in the temperature range and the voltage Vbb1 is applied to the bodies, a leakage of the die is not more than the target acceptable leakage level.

16. The system of claim 15, wherein the die includes additional FETs, at least some of which are not forward body biased.

17. The system of claim 15, wherein if the temperature reduction system were not operated, and a voltage Vbb2 were applied to the bodies, then the leakage would not be above the target acceptable leakage level, where Vbb1 is more than 15% greater than Vbb2.

18. The system of claim 15, wherein if the temperature reduction system were not operated, and a voltage Vbb2 were applied to the bodies, then the leakage would not be above the target acceptable leakage level, where Vbb1 is more than 25% greater than Vbb2.

19. An electrical system, comprising:
a die including p-channel field effect transistors (PFETs) and n-channel field effect transistors (NFETs), the die having a target acceptable leakage level, the FETs each having an I_{OFF} level that is greater than would be acceptable to meet the target acceptable leakage level without temperature reduction;
body bias voltage sources to apply a voltage Vbbp1 to bodies of the PFETs to forward body bias the PFETs and apply a voltage Vbbn1 to bodies of the NFETs to forward body bias the NFETs; and
a temperature reduction system to provide a temperature reduction to the die such that the die is in a temperature range, and wherein when the temperature of the die is in the temperature range and the voltages Vbbp1 and Vbbn1 are applied to the bodies, a leakage of the die is not more than the target acceptable leakage level.

20. The system of claim 19, wherein the die includes additional FETs, at least some of which are not forward body biased.

21. The system of claim 19, wherein if the temperature reduction system were not operated, and voltages Vbbp2 and Vbbn2 were applied to the bodies of the PFETs and NFETs, respectively, then the leakage would not be above the target acceptable leakage level, where Vbbp1 is more than 15% greater than Vbbn2 and Vbbn1 is more than 15% greater than Vbbp2.

22. The system of claim 19, wherein if the temperature reduction system were not operated, and voltages Vbbp2 and Vbbn2 were applied to the bodies of the PFETs and NFETs, respectively, then the leakage would not be above the target acceptable leakage level, where Vbbp1 is more than 25% greater than Vbbn2 and Vbbn1 is more than 15% greater than Vbbp2.
